(19) United States
(12) Patent Application Publication
(10) Pub. No.: US 2010/0037932 A1
(43) Pub. Date: Feb. 18, 2010

(54) SYSTEM FOR SIMULTANEOUS TABBING AND STRINGING OF SOLAR CELLS

(76) Inventors: Shmuel Erez, San Jose, CA (US); Gerald Schock, Campbell, CA (US); Mahendran Chidambaram, Saratoga, CA (US)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(21) Appl. No.: 12/477,723

(22) Filed: Jun. 3, 2009

Related U.S. Application Data
(60) Provisional application No. 61/058,446, filed on Jun. 3, 2008.

(51) Int. Cl. H01L 31/042; H01L 31/18

(52) U.S. Cl. 136/244; 29/890.033; 438/67

(57) ABSTRACT

A method for stringing photovoltaic (PV) cells together and a system for the combined tabbing and stringing of photovoltaic (PV) cells for assembly into solar cell arrays. Multiple ribbons are first soldered simultaneously (or nearly so) to the front and back surfaces of individual PV cells (tabbing). After tabbing, PV cells are then loaded into a stringer subsystem which solders the front side ribbons of a first PV cell to the back side ribbons of the neighboring PV cell to form strings of PV cells wired in series. The tabber stringer system then loads completed strings into a frame containing a solar cell array being manufactured. The dual-ribbon method of PV cell interconnection reduces the electrical resistance between the cells in a string, thereby raising the solar cell array output power.

### RELATED APPLICATIONS

This application is a NONPROVISIONAL and claims the priority benefit of U.S. Provisional Patent Application 61/058,446, filed Jun. 3, 2008, which is incorporated herein by reference.

### FIELD OF THE INVENTION

This invention relates to the manufacture of solar cell arrays, and, in particular, to photovoltaic device interconnection methods and related apparatus for solar cell manufacturing.

### BACKGROUND

Traditionally, photovoltaic (PV) cells are interconnected using a “tabbing and stringing” technique of soldering two or three conductive ribbons to the front surface of a first solar cell and to the back surface of an adjacent cell. Typically, N (where N could be ten or twelve) PV cells are interconnected in this manner across one dimension of a solar array being manufactured. The process of attaching the ribbons to the PV cells is called “tabbing” and the process of connecting multiple PV cells together is called “stringing”. A typical solar array might have “strings” of N PV cells connected together in series, where a number, M, of strings (e.g., six) are then electrically connected together in parallel. The power output of the completed solar array is then the product of the voltage generated by each string (N times the voltage generated by each PV cell) times the sum of the currents generated by all strings (M times the current of a single string). Other interconnection methodologies are also used, such as shingled interconnects with conductive adhesives to allow a continuous path for the current.

One drawback with the “tabbing and stringing” method is the poor yield and reliability of the solder joints that fail due to thermal coefficient of expansion mismatches and soldering defects. These solder joints require significant labor and capital equipment to assemble and do not allow the PV cells to be closely packed since gaps must be left between adjacent PV cells in the solar array to allow space for the tabbed electrical interconnects between adjacent PV cells.

### SUMMARY OF THE INVENTION

In conventional PV cell stringing methods, a single ribbon attaches along the front surface of a first PV cell (soldered to a bus bar on the first PV cell front surface), extends past the PV cell edge, then bends down and attaches along the bottom of the neighboring cell (soldered to a bus bar on the second PV cell back surface). One aspect of the present invention includes a mono/multi crystalline silicon photovoltaic module comprising, a first photovoltaic cell (PV cell) with a top interconnect tab (ribbon) and a second photovoltaic cell with a bottom interconnect tab (ribbon). The advantage of this improved PV cell interconnection method is improved quality of the soldering of the ribbons to the PV cell bus bars since this soldering operation is done separately from the stringing operation which interconnects neighboring PV cells. Neighboring cells are instead interconnected by the separate soldering step which attaches a first ribbon from a first PV cell to a second ribbon from the neighboring second PV cell—this soldering operation may be accomplished with a soldering head separate from those used to attach the front and back surface ribbons to the bus bars on the PV cells.

Another aspect of the present invention is a system for the tabbing of PV cells—this is the process step in which ribbons are attached to the front and back surfaces (onto bus bars) of a single wafer. The front side ribbons (typically two or three) are arranged to overhang one edge of the wafer from the front surface of the wafer, and the back side ribbons (the same number as for the front side ribbons) are arranged to overhang the opposite edge of the wafer. Soldering heads are pressed against the front and back surfaces simultaneously (or nearly so) to rapidly head the ribbon to enable low-stress solder bonds between the ribbons and the bus bars on the wafer. Further ribbon-to-wafer stress reduction may be accomplished by means of a sequencing method in which only selected portions of the ribbon are heated at any one time, and the spatial relationships of the heated portions are selected to reduce the relative thermal expansion between the ribbons and the wafer, thereby enhancing ribbon-to-wafer adhesion.

A still further aspect of the present invention is a method for stringing PV cells together to form “strings” of PV cells wired in series, typically with 10 to 12 cells each. When a string is completed, it is transferred to a secondary belt which supports the string prior to the loading of the string into the solar array being assembled. This method improves overall system throughput since the next string can be started before the just-completed string has been transferred into the solar array.

Another aspect of the present invention is the use of a rotary turntable including multiple bins for PV cells: For example, a system with three such bins may include a first bin from which PV cells (wafers) are loaded into the tabbing subsystem, a second bin in which PV cells are loaded by the system operator or an external robotic apparatus, and a third bin for storage of rejected PV cells. When all the PV cells have been loaded into the tabbing system from the first bin, the turntable rotates to position the second bin for loading PV cells into the tabbing subsystem while new PV cells are being loaded into the first bin. This aspect of the present invention improves throughput since the tabber stringer system experiences minimal idle time waiting for PV cells to be loaded.

### BRIEF DESCRIPTION OF THE DRAWINGS

FIG. 1 shows a close-up isometric view of the tabber-stringer system performing the wafer pickup operation.

FIG. 2 shows an isometric view of a complete tabber-stringer system configured in accordance with an embodiment of the present invention.

FIG. 3 shows a close-up isometric view of a tabber-stringer system configured in accordance with an embodiment of the present invention.

FIG. 4A shows a top view of the turntable in position #1.

FIG. 4B shows a top view of the turntable in position #2.

FIG. 5 shows a close-up isometric view of a complete tabber-stringer system performing the wafer align operation,

FIG. 6 shows a close-up isometric view of the tabber-stringer system performing the wafer inspection operation.

FIG. 7 shows a close-up isometric view of the tabber-stringer system performing the wafer rejection operation.

FIG. 8 shows a close-up isometric view of the tabber-stringer system performing the ribbon grabber reach-in operation.

FIG. 9 shows a close-up isometric view of the tabber-stringer system performing the ribbon grabbing operation.

FIG. 10 shows a close-up isometric view of the tabber-stringer system performing the ribbon pulling operation.

FIG. 11 shows a close-up isometric view of the tabber-stringer system after completion of the ribbon pulling operation.

FIG. 12 shows a close-up isometric view of the tabber-stringer system performing the soldering head clamping operation.

FIG. 13 shows a close-up isometric view of the tabber-stringer system performing the ribbon soldering operation.

FIG. 14 shows a close-up isometric view of the tabber-stringer system after completion of the ribbon soldering operation.

FIGS. 15A-15K are schematic views of the steps illustrated in FIGS. 9-14.

FIG. 16 shows a schematic top view of a PV cell, illustrating the zones for soldering the ribbon to the wafer.

FIG. 17 shows a close-up isometric view of the tabber-stringer system performing the wafer transfer to the belt operation.

FIG. 18 shows a close-up isometric view of the tabber-stringer system performing the wafer stringing operation.

FIG. 19 is a schematic side cross-sectional view of the tab-over method of stringing.

FIG. 20 is a schematic side cross-sectional view of the extended tab method of stringing.

FIG. 21 is a schematic side cross-sectional view of the conductive path method of stringing.

FIG. 22 shows a close-up isometric view of the tabber-stringer system performing the wafer indexing operation.

FIG. 23 shows a close-up isometric view of the tabber-stringer system resetting the vacuum arm.

FIG. 24 shows a close-up isometric view of the tabber-stringer system performing the stringing and buffering operation.

### DETAILED DESCRIPTION

Described herein is a system configured for the combined tabbing and stringing of photovoltaic solar cells (PV cells or wafers) together, and the subsequent assembly of strings of PV cells into a solar cell array. The system includes the following main subsystems:
1) Wafer bin turntable—this turntable contains multiple (e.g., three) bins: for example, one bin containing wafers being individually loaded into the tabbing subsystem, a second bin being loaded with wafers, and a third bin for rejected wafers. In other embodiments, more than three bins may be used. For example, alternating pairs of wafer containing bins may be used to provide multiple operational positions, as will be apparent from the discussion below. This may be especially useful where tabbing and stringing operations are performed by pairs of assemblies (e.g., two such assemblies, four such assemblies, etc.).
2) Vacuum arm wafer transfer subsystem—transfers wafers between the bins, tabbing subsystem and stringing subsystem.
3) Tabbing subsystem—solders ribbons to the front and back sides of a wafer, with appropriate overhangs to enable stringing.
4) Stringing subsystem—solders wafers together to form strings of wafers up to N (e.g., 12) wafers in length.
5) Solar cell array assembly subsystem—takes completed strings from the stringing subsystem and loads them into a solar array being manufactured. A typical solar cell array may have up to at least six strings, each with twelve cells, for a total of 72 PV cells generating roughly 225 W.
   Each of the above subsystems in described in detail below.

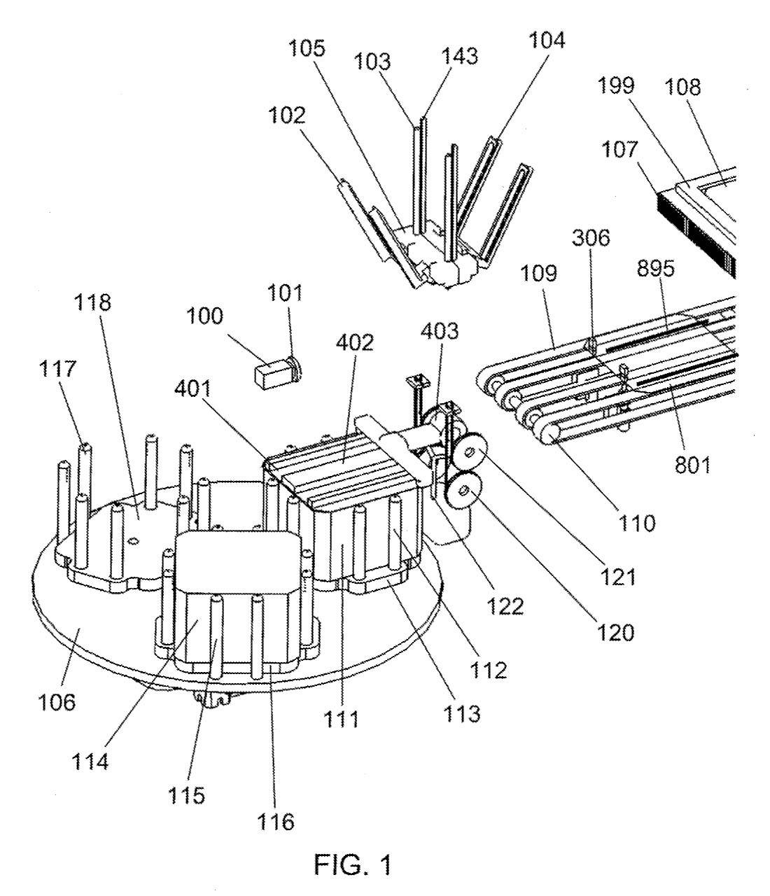

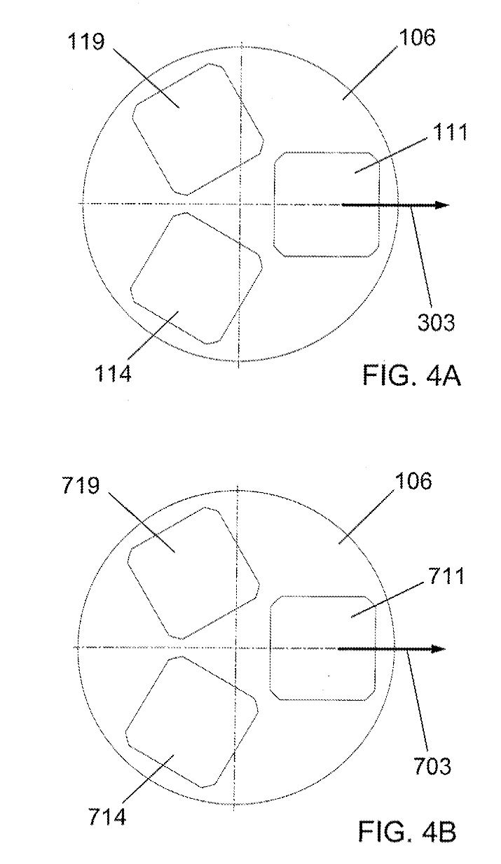

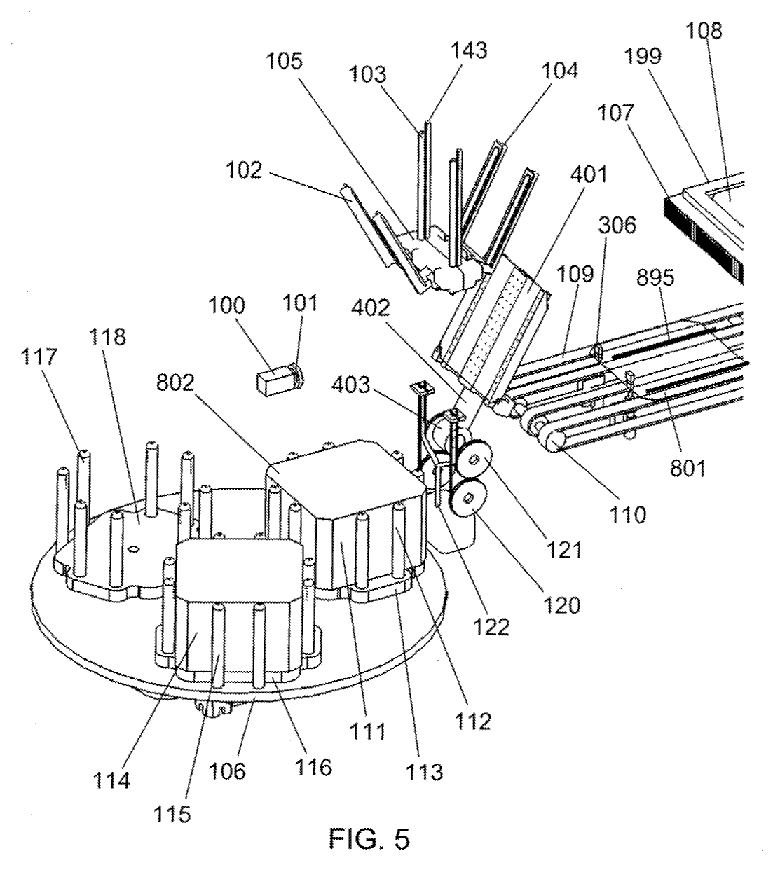

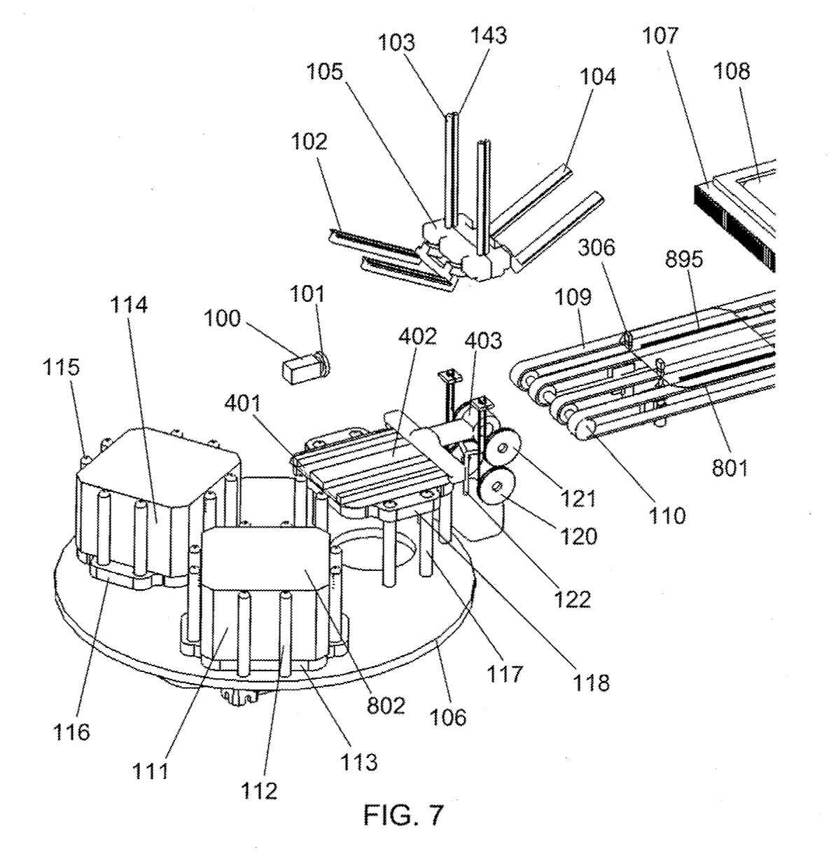

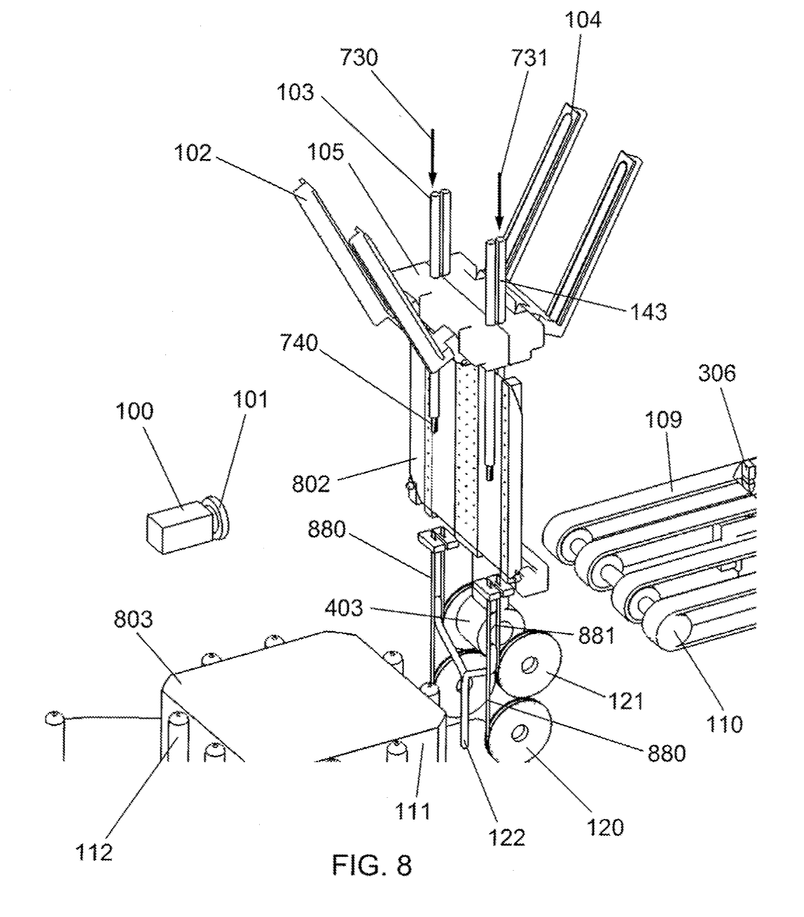

FIG. 1 shows a close-up isometric view of the tabber-stringer system performing the wafer pickup operation. The turntable 106 has three base plates: base plate #1 113 which, in this example, is supporting wafer stack 111, base plate #2 116 which supports wafer stack 114, and base plate #3 118 which collects rejected wafers (see FIGS. 6 and 7). Guide posts 112, 115, and 117 are fixedly attached to turntable 106 and slide through holes in base plates 113, 116, and 118. An actuator (not shown) is mounted adjacent to the vacuum arm mechanism comprising arm 402 and pivot 403. For the orientation of turntable 106 shown in FIG. 1, the actuator serves to move base plate 113 up and down, thereby positioning the top wafer (wafer 401 in this example) at the proper height to be picked up by vacuum arm 402. When turntable 106 is rotated 120° clockwise, base plate 118 is positioned over the actuator to enable rejected wafers to be removed from vacuum arm 402. When turntable 106 is rotated 120° counterclockwise, base plate 116 is positioned over the actuator to enable wafers from stack 114 to be picked up by vacuum arm 402 (see FIGS. 4A and 4B).

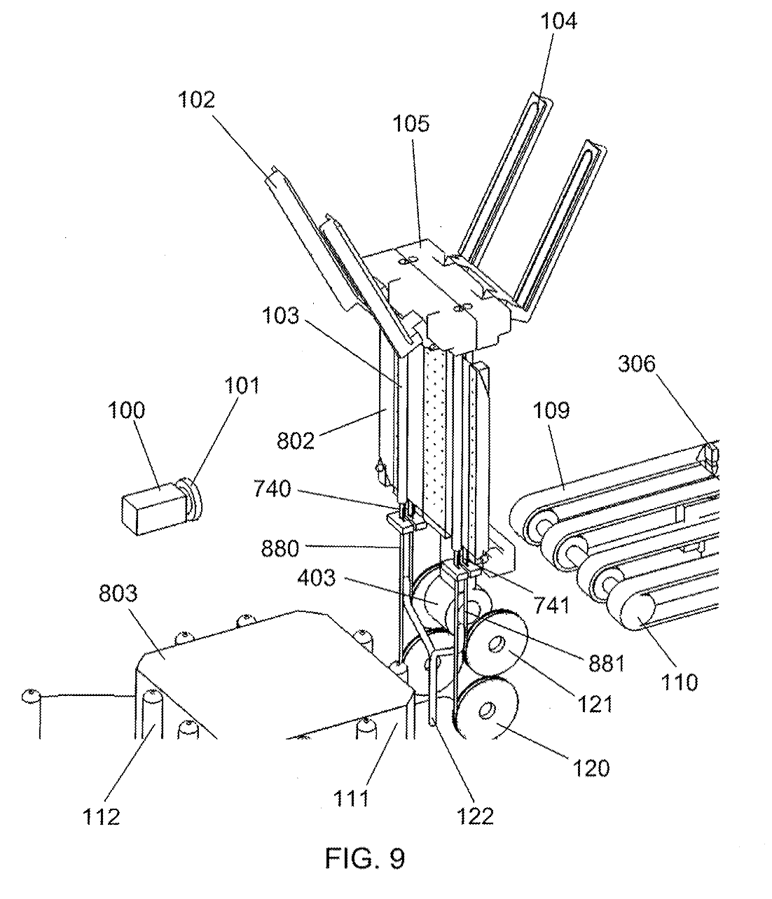

Vacuum arm 402 is shown in the wafer pick-up position, on top of wafer 401. Vacuum arm 402 is a fork-like structure comprising three tines, in this example, each with a plurality of small holes and connected to a vacuum pump to exert an even and gentle clamping force to the wafer being picked up. This gentle clamping force enables thin wafers to be processed by the tabber stringer system of the present invention. Vacuum arm 402 swings around pivot 403, driven by a rotary drive actuator (not shown). Camera 100 and lens 101 are part of the wafer imaging system (see FIG. 6). Two or more solder reels 120 feed at least two ribbons to the front surfaces of the wafer being tabbed (see FIGS. 8-15J). Similarly, two or more solder reels 121 feed at least two ribbons to the back surfaces of the wafer being tabbed (see FIGS. 8-15K).

Front-side soldering heads 102, back-side soldering heads 104, front-side ribbon puller 103, back-side ribbon puller 143, and support block 105 comprise the ribbon soldering head. Belts 109 and rollers 110 serve to support and index wafers after tabbing, and during stringing. Stringer soldering heads 306 perform the stringing soldering operation. A wafer 801 with soldered-on ribbons 895 is supported by belts 109 and has been indexed over one position to await the next stringing operation. Table 107 supports solar array frame 199 during assembly of multiple strings into a solar array. Wafer 108 is shown within solar array frame 199.

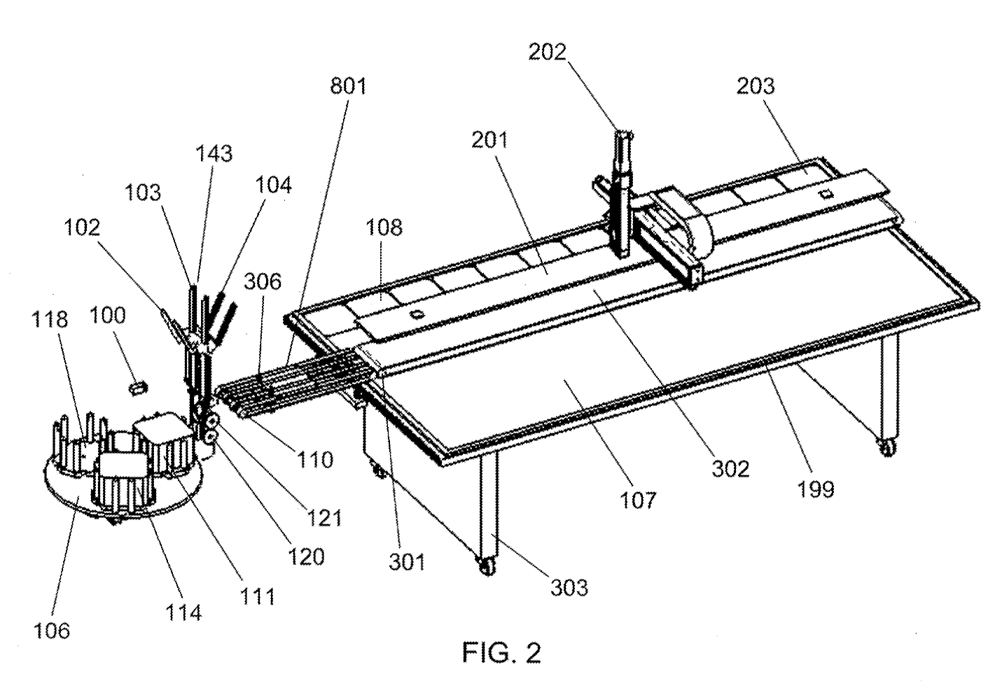

FIG. 2 shows an isometric view of a complete tabber-stringer system configured in accordance with an embodiment of the present invention. Belt 302, moved by rollers 301, supports each string as it is being soldered together. Once the final wafer for each string has been soldered to the string-in-progress, the completed string is moved out onto belt 302, thereby freeing up belts 109 to support the initial wafers for the next string-in-progress. This dual belt scheme maximizes system throughput by freeing up the tabber-stringer mechanism from having to wait for completion of the array assembly operation.

Once a completed string (not shown) has been moved out onto belt 302, vacuum chuck 201 is moved down onto the completed string, which is then lifted by the vacuum force of the vacuum chuck 201, moved up by mechanism 202. Table 107, supported by table support legs 303, is movable along an axis perpendicular to the motion axis of belt 302, enabling completed strings to be loaded into solar array frame 199. Typical wafers in the first string to be loaded into frame 199 are wafers 108 and 203.

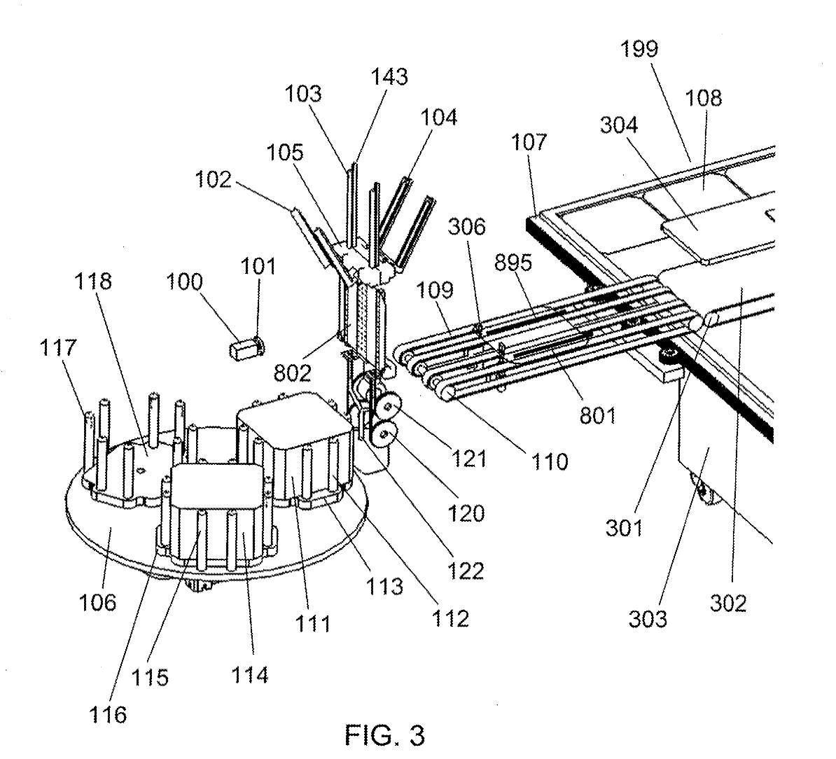

FIG. 3 shows a close-up isometric view of the tabber-stringer system embodying the present invention. In this view, vacuum arm 402 has rotated 90° from the position shown in FIG. 1 to position wafer 802 in a vertical orientation. In this position, visual inspection of wafer 802 (e.g., for defects such as cracks, chips, etc.) is accommodated (see FIG. 6). The wafer does not yet have the front and back ribbons soldered into place.

FIG. 4A shows a top view of the turntable in position #1. In this turntable orientation, wafer stack 111 is supported by base plate #1 113 (see FIG. 1), wafer stack 114 is supported by base plate #2 116, and wafer stack 119 (rejected wafers) is supported by base plate #3 118. Arrow 303 shows the direction in which wafers are individually removed by vacuum arm 402 for tabbing and subsequent stringing in the system according to the present invention. Wafer stack 114 is being loaded into the system simultaneously with the unloading of stack 111 by vacuum arm 402. This enables maximum system throughput since the system does not need to wait for wafer loading before beginning tabbing and stringing operations.

FIG. 4B shows a top view of the turntable in position #2. In this turntable orientation (turntable 106 rotated 120° counterclockwise relative to the turntable orientation shown in FIG. 4A), wafer stack 711 is supported by base plate #2 116 (see FIG. 1), wafer stack 719 is supported by base plate #1 113, and wafer stack 714 (rejected wafers) is supported by base plate #3 118. Arrow 703 shows the direction in which wafers are individually removed by vacuum arm 402 for tabbing and subsequent stringing in the system according to the present invention. Wafer stack 719 is being loaded into the system simultaneously with the unloading of stack 711 by vacuum arm 402.

The system remains in the configuration shown in FIG. 4A until all of stack 111 has been loaded into the system, then turntable 106 rotates 120° counterclockwise to position stack 711 for loading into the system as shown in FIG. 4B. Once stack 711 has been fully loaded into the system (one wafer at a time), turntable 106 rotates 120° clockwise to return to the position shown in FIG. 4A. Thus, at all times a stack of wafers is available for loading into the tabber stringer mechanism while another stack of wafers is being loaded into the system.

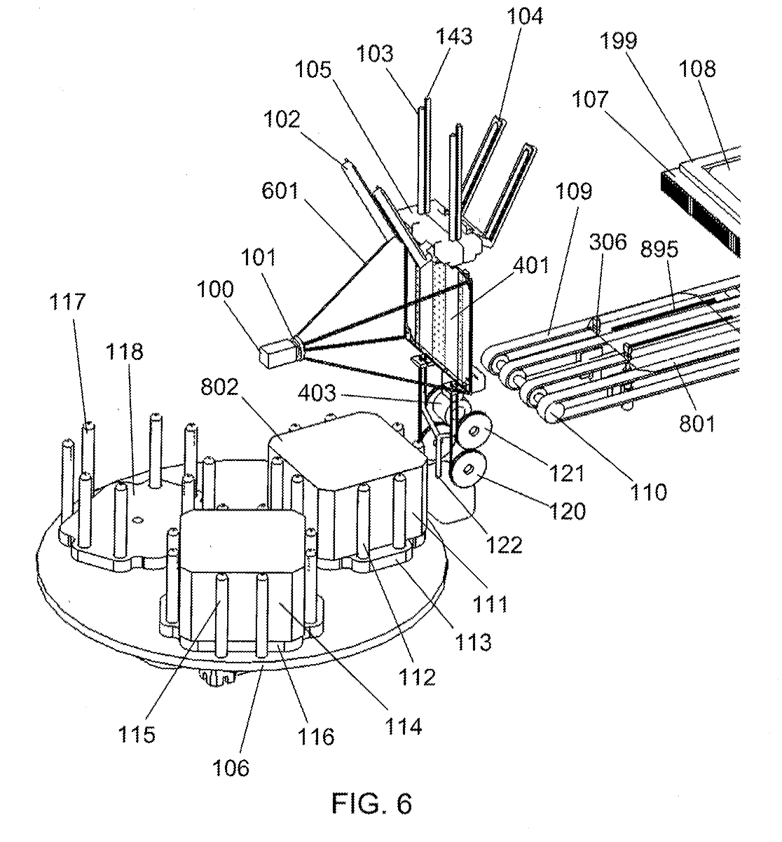

FIG. 5 shows a close-up isometric view of a complete tabber-stringer system performing the wafer align operation. Vacuum arm 402 has rotated away from the (vertical) inspection position, towards belts 109. The vacuum force is then relaxed, enabling wafer 401 to move down against a set of alignment pins (not shown). The vacuum arm 402 is then reactivated to reclamp wafer 401. This sequence ensures that each wafer on the vacuum arm is in the same position prior to initiating the tabbing operation—this, in turn, ensures that the ribbons are always attached to the wafers in the same locations, important for ribbon-to-ribbon alignment during stringing.

An alternative method for wafer alignment is to use the imaging camera 100 to determine the position of the wafer 401 on the vacuum arm 402, and then reorient vacuum arm 402 in two dimensions to compensate for any wafer position errors prior to tabbing and stringing. This method has the advantage of higher speed (since no separate alignment step as shown in FIG. 5 is required) and also possibly lower wafer damage since no sliding of the wafer relative to the vacuum arm 402 is required. The disadvantage of this alternative alignment method is the requirement for two-dimensional movement of the vacuum arm relative to the ribbon soldering mechanism and belts 109.

FIG. 6 shows a close-up isometric view of the tabber-stringer system performing the wafer inspection operation. Wafer 401 is backlit by an illuminator (not shown). Camera 100 then images wafer 401 through lens 101, forming an image which is acquired by a computer-based image analysis system (not shown). The image analysis system processes the wafer image, looking for cracks or chips in the wafer (typically around the wafer edges). If the alternative wafer alignment method described above is used, the image analysis system also locates the edges of the wafer in two dimensions and determines a wafer positional error vector. This positional error vector is then used by the vacuum arm actuation mechanism to displace the vacuum arm (and thus the wafer clamped to it) by the proper amount to enable the front and back ribbons to be soldered in the proper positions.

After the image analysis system has processed the wafer image and determined whether the wafer is damaged, a decision is made: should the wafer be used in the solar array being manufactured or should the wafer be rejected? The criterion for rejection is a pre-determined degree of acceptable damage to the wafer. If the degree of damage is below the acceptable limit, then the wafer can be used in the solar array being manufactured and vacuum arm 402 will remain in the vertical position to enable soldering of the front and back ribbons to the wafer in the “tabbing” operation. If the degree of damage exceeds the degree of acceptable damage, the wafer will be rejected and not stringed together with other (previously accepted) wafers.

FIG. 7 shows a close-up isometric view of the tabber-stringer system performing the wafer rejection operation, following a decision (with respect to the inspection process described in conjunction with FIG. 6) that the degree of damage to the wafer exceeds acceptable levels. First, turntable 106 rotates so as to position base plate #3 118 over the actuator (not shown). The actuator then moves base plate #3 118 vertically (guided by pins 117) to the proper height to accept rejected wafer 401. Now, vacuum arm 402 rotates so as to place rejected wafer 401 onto base plate #3 118 (which may already be supporting a number of previously-rejected wafers). Vacuum arm 402 then releases rejected wafer 401 and returns to a vertical position, while the actuator lowers base plate #3 118 to the bottom position. Turntable 106 then rotates to position base plate #1 113 over the actuator once again.

The actuator is designed to move vertically through three holes in turntable 106, enabling base plates 113, 116, and 118 to be moved up and down (only one at a time). During rotation of turntable 106, the actuator is lowered beneath the bottom surface of turntable 106 to enable free rotation of turntable 106.

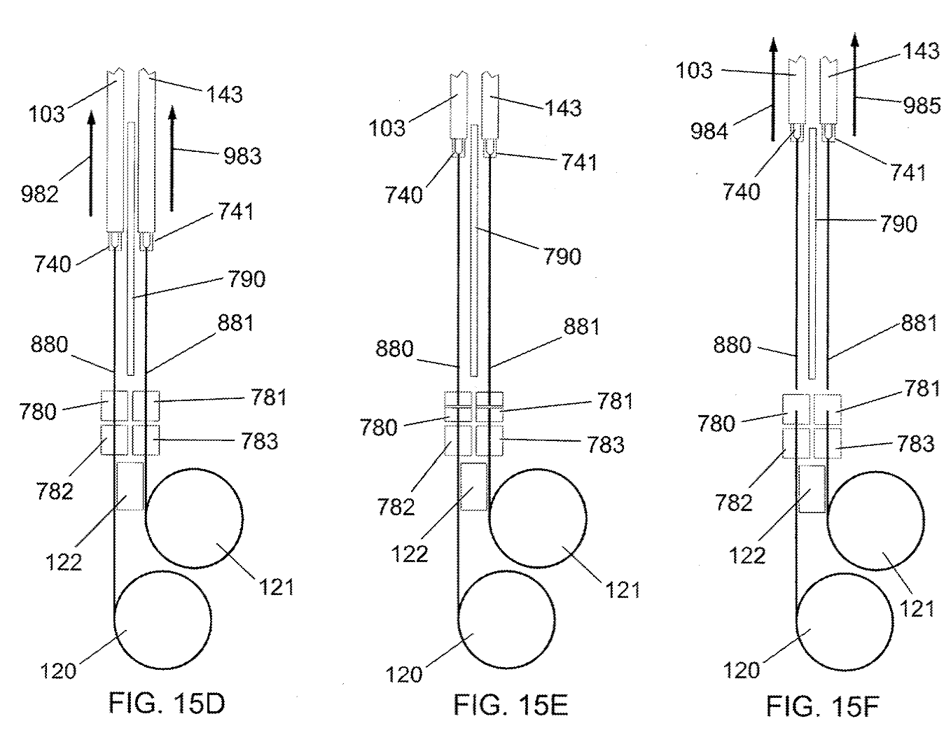

FIG. 8 shows a close-up isometric view of the tabber-stringer system performing the ribbon grabber reach-in operation. The two front side ribbon pullers 103 are moving down as shown by arrow 730. Simultaneously, the two back side ribbon pullers 143 are moving down as shown by arrow 731. See also FIG. 15B, where arrow 980 corresponds to arrow 730, and arrow 981 corresponds to arrow 731.

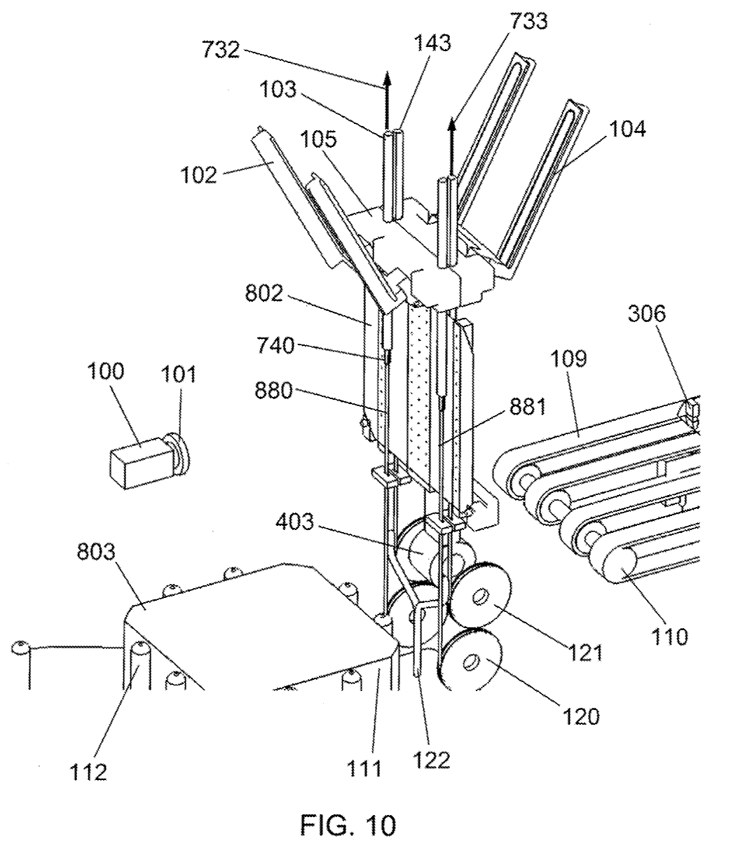

FIG. 9 shows a close-up isometric view of the tabber-stringer system performing the ribbon grabbing operation. The two front side ribbon pullers 103 have moved down far enough so that front side ribbon grabber 740 can grip front side ribbon 880. The two back side ribbon pullers 143 have moved down far enough so that back side ribbon grabber 741 can grip back side ribbon 881. See also FIG. 15C.

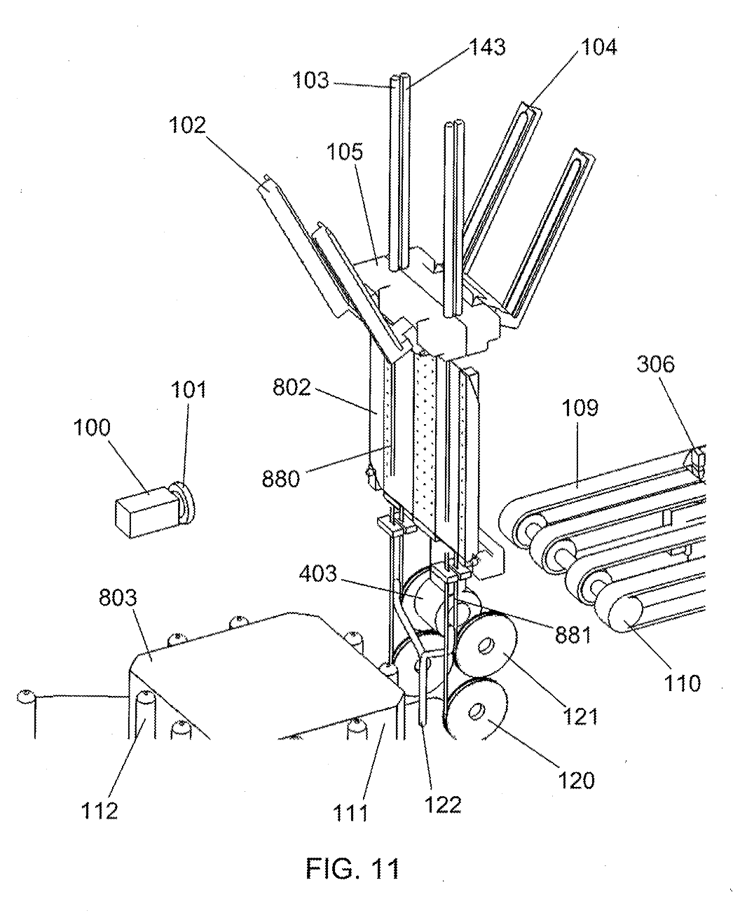

FIG. 10 shows a close-up isometric view of the tabber-stringer system performing the ribbon pulling operation. The two front side ribbon pullers 103 are moving up as shown by arrow 732. Simultaneously, the two back side ribbon pullers 143 are moving up as shown by arrow 733. See also FIG. 15D, where arrow 982 corresponds to arrow 732, and arrow 983 corresponds to arrow 733. As front side ribbon pullers 103 move up, front side ribbon grabbers 740 pull front side ribbons 880 through front side ribbon cutters 780 and front side ribbon extenders 782 (see FIG. 15D). As back side ribbon pullers 143 move up, back side ribbon grabbers 741 pull back side ribbons 881 through back side ribbon cutters 781 and back side ribbon extenders 783 (see FIG. 15D). While front side ribbons 880 and back side ribbons 881 are moving up, flux applicators 122 (one per pair of front side ribbon and back side ribbon) deposit flux on the sides of the ribbons 880 and 881 facing wafer 802. See also FIG. 15E.

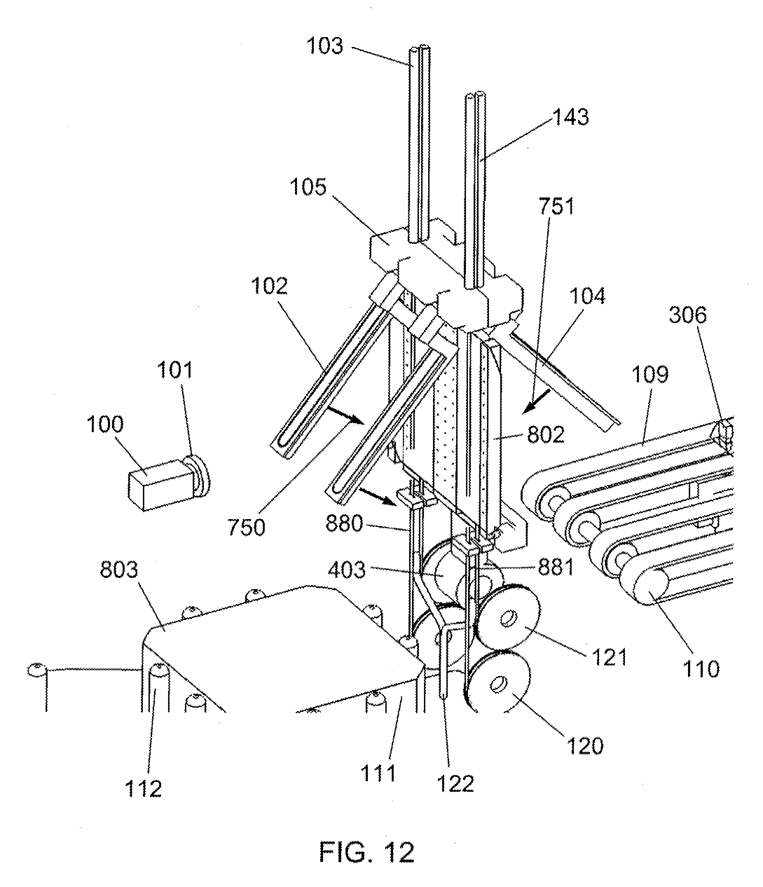

FIG. 11 shows a close-up isometric view of the tabber-stringer system after completion of the ribbon pulling operation. This is illustrated also in FIG. 15F.

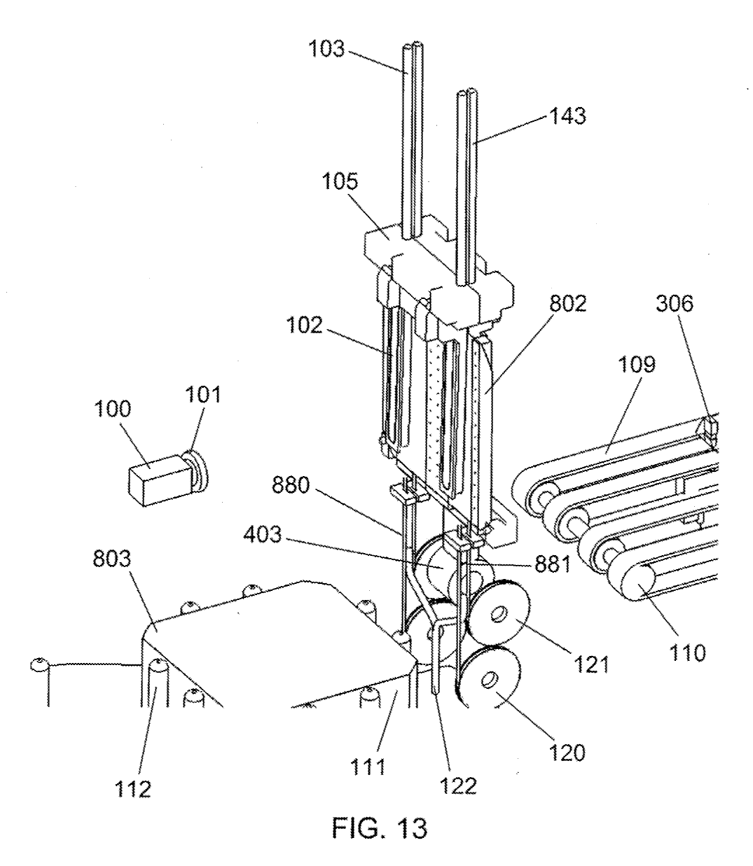

FIG. 12 shows a close-up isometric view of the tabber-stringer system performing the soldering head clamping operation. Front side soldering heads 102 are swinging down (arrow 750) towards the front side of wafer 802. Back side soldering heads 104 are swinging down (arrow 751) towards the back side of wafer 802.

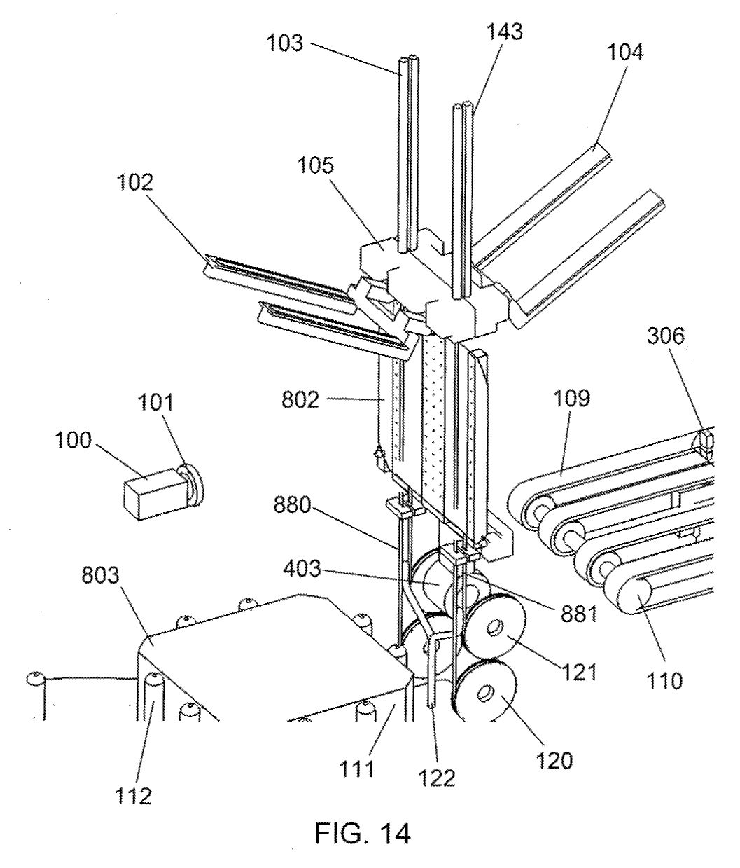

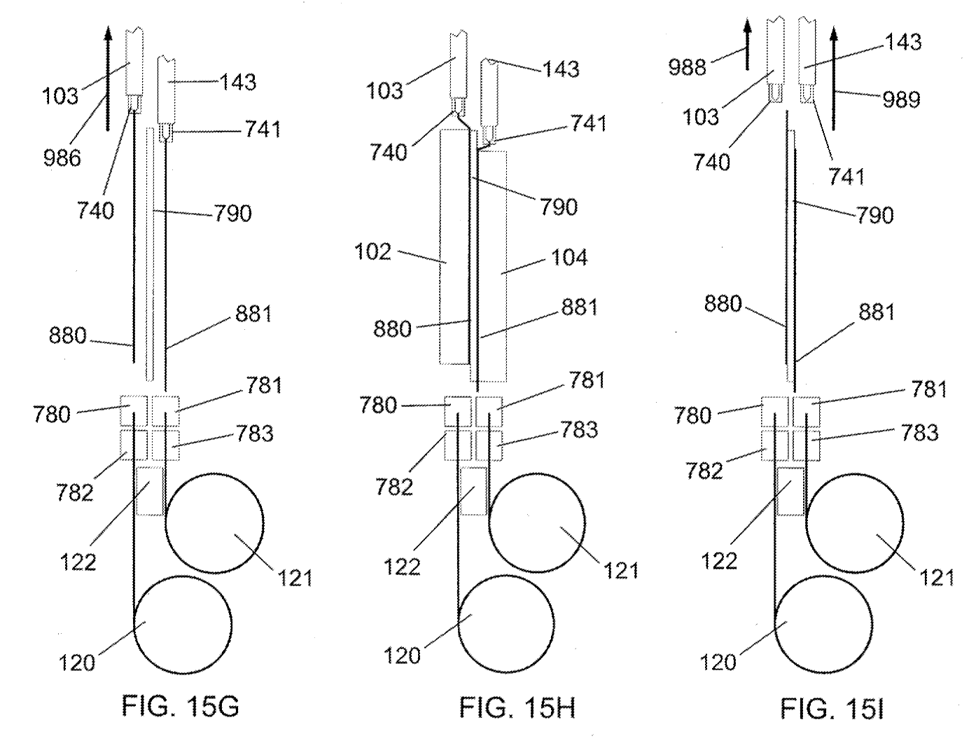

FIG. 13 shows a close-up isometric view of the tabber-stringer system performing the ribbon soldering operation—see also FIG. 15H. Front side soldering head 102 is pressed against front side ribbon 880 to ensure that it is properly soldered to the front side of wafer 802. Back side soldering head 104 is pressed against back side ribbon 881 to ensure that it is properly soldered to the back side of wafer 802. The discussion of FIG. 16, below, gives further details on the ribbon soldering process.

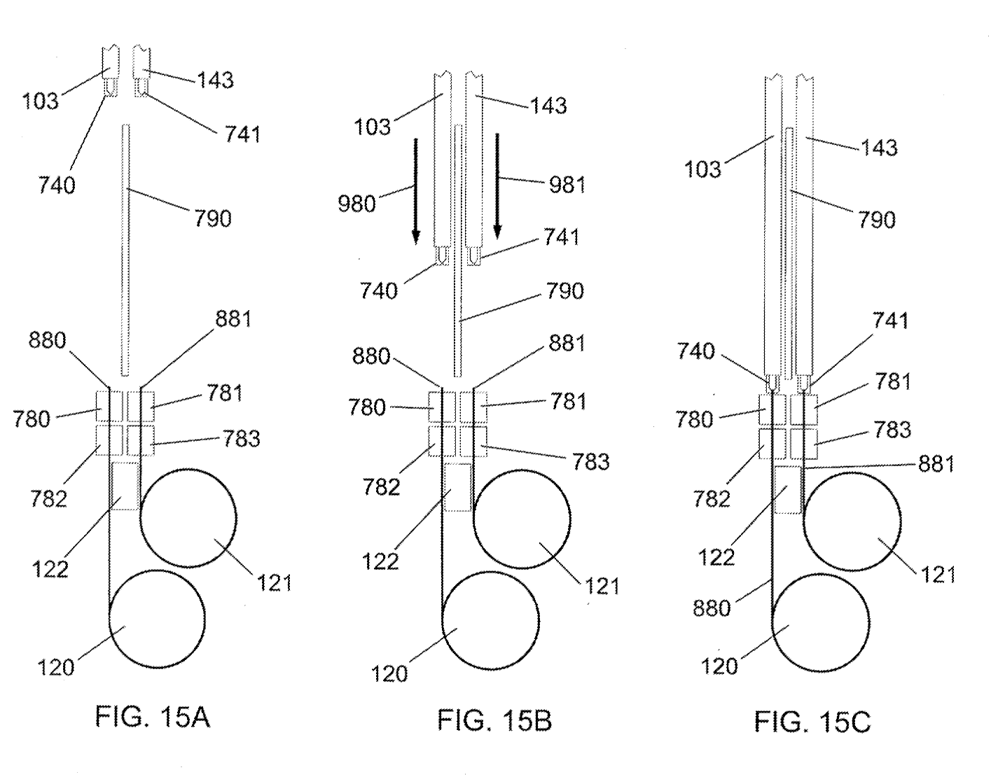

FIG. 14 shows a close-up isometric view of the tabber-stringer system after completion of the ribbon soldering operation—see also FIG. 15I.

FIGS. 15A-15K are schematic views of the steps illustrated in FIGS. 9-14. Wafer 790 corresponds to wafer 802 in FIGS. 8-14.

In FIG. 15A, ribbon pullers 103 and 143 are still above the upper edge of wafer 790, and the upper ends of ribbons 880 and 881 are below the lower edge of wafer 790. This view corresponds to FIG. 3.

In FIG. 15B, front side ribbon pullers 103 are moving down, carrying front side ribbon grabbers 740 towards the upper ends of front side ribbons 880. Back side ribbon pullers 143 are moving down, carrying back side ribbon grabbers 741 towards the upper ends of back side ribbons 881. This view corresponds to FIG. 8.

In FIG. 15C, front side ribbon pullers 103 have moved all the way down, placing front side ribbon grabbers 740 at the proper positions to grab front side ribbons 880. Back side ribbon pullers 143 have moved all the way down, placing back side ribbon grabbers 741 at the proper positions to grab back side ribbons 881. This view corresponds to FIG. 9.

In FIG. 15D, front side ribbon grabbers 740 are holding front side ribbons 880 while front side ribbon pullers 103 are moving upwards (arrow 982). Back side ribbon grabbers 741 are holding back side ribbons 881 while back side ribbon pullers 143 are moving upwards (arrow 983). As front side ribbons 880 move upwards, they slide through front side ribbon cutters 780 and front side ribbon extenders 782. As back side ribbons 881 move upwards, they slide through back side ribbon cutters 781 and back side ribbon extenders 783. While front side ribbons 880 and back side ribbons 881 are moving up, flux applicators 122 (one per pair of front side ribbon and back side ribbon) deposit flux on the sides of the ribbons 880 and 881 facing wafer 802. This view corresponds to FIG. 10.

In FIG. 15E, front side ribbon cutters 780 have just cut front side ribbons 880, and back side ribbon cutters 781 have just cut back side ribbons 881. This cutting operation may occur while ribbons 880 and 881 are moving upwards, or may occur after ribbon pullers 103 and 143 have momentarily stopped upwards motion of ribbons 880 and 881.

In FIG. 15F, front side ribbon pullers 103 continue to pull (arrow 984) front side ribbons 880 upwards after front side ribbons 880 were cut by front side ribbon cutters 780 (see FIG. 15E). Back side ribbon pullers 143 continue to pull (arrow 985) back side ribbons 881 upwards after back side ribbons 881 were cut by back side ribbon cutters 781. Eventually front side ribbons 880 are pulled completely through front side ribbon cutters 780, while back side ribbons 881 are pulled completely through back side ribbon cutters 781.

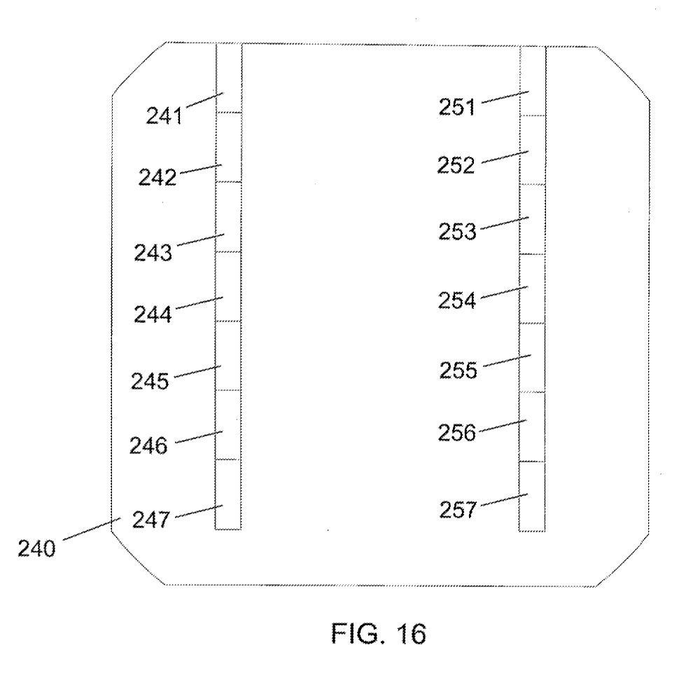

In FIG. 15G, the motion of the front and back side ribbon pullers 103 and 143, respectively, diverges. Front side ribbon puller 103 continues to move upwards (arrow 986) while back side ribbon puller 143 is stopped. The reason for this differing motion is that for proper stringing (see FIGS. 18-21), it is necessary for the front side ribbons to be offset upwards relative to the back side ribbons. This enables the front side ribbon to hang over the upper edge of wafer 790, while the back side ribbon hangs over the lower edge of wafer 790. It is necessary for front side ribbon puller 103 to move up (arrow 986) a sufficient distance to enable front side ribbons 880 to overhang the upper edge of wafer 790 by the proper amount (typically 3-4 mm) for stringing. Similarly, it is necessary for back side ribbon puller 143 to move up a shorter distance to enable back side ribbons 881 to overhang the lower edge of wafer 790 by the proper amount (typically 3-4 mm). When this pulling operation is complete, the front side ribbons 880 and back side ribbons 881 are in the proper position for soldering in FIG. 15H (see also FIG. 13). Of course, in an alternative arrangement one could allow the front side ribbon to protrude over the lower edge of wafer 790 and the back side ribbon to protrude over the upper edge thereof.

In FIG. 15H, the ribbon soldering operation is illustrated. Front side soldering heads 102 have swung down (see FIG. 12) and are now pressing front side ribbons 880 against front side contact areas on wafer 790 (wafer 802 in FIG. 13). Back side soldering heads 104 have swung down (see FIG. 12) and are now pressing back side ribbons 881 against back side contact areas on wafer 790. It is preferable that the front side and back side soldering heads, 102 and 104, respectively, contact wafer 790 approximately simultaneously to ensure that no unnecessary asymmetrical (front-to-back) forces are applied to wafer 790. In particular, if back side soldering heads 104 were to contact the back side of wafer 790 before front side soldering heads 102 contacted the front side of wafer 790, it is possible that wafer 790 could be disconnected from vacuum arm 402, causing either wafer misalignment or wafer damage. After soldering is complete, ribbon grabbers 740 and 741 release ribbons 880 and 881, respectively.

In FIG. 15I, the front and back side soldering heads 102 and 104, respectively, have swung back to their upper positions (see FIG. 14). At the same time, ribbon pullers 103 and 104 move up (arrows 988 and 989, respectively) to position ribbon grabbers 740 and 741 above the upper edge of wafer 790. The offset configuration of the front 880 and back 881 ribbons can be seen clearly here.

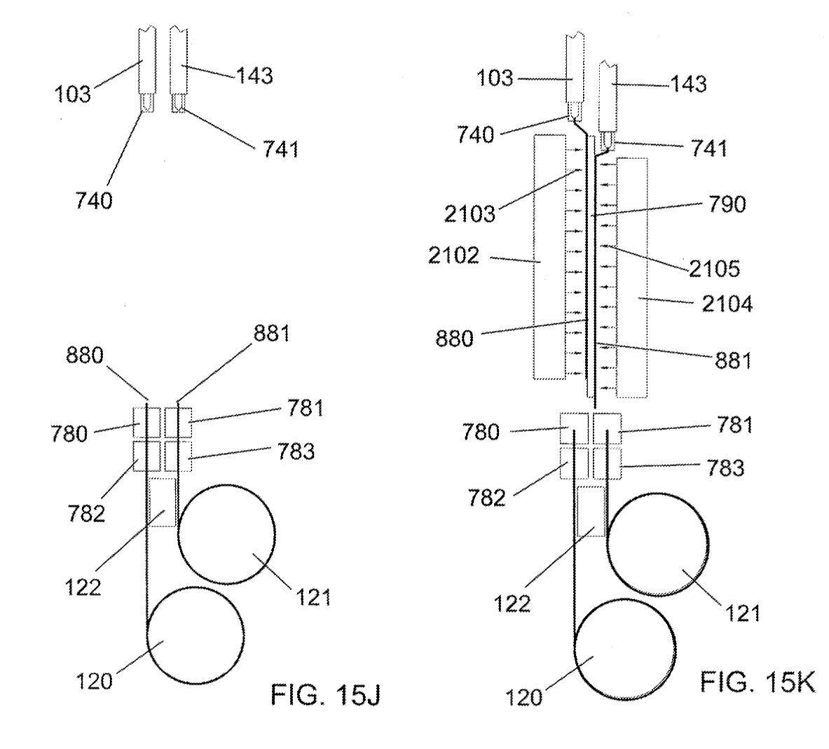

FIG. 15J, wafer 790 has been moved out of the soldering mechanism towards belts 109 (see FIG. 17). Ribbon pullers 103 and 143 remain in their full up position. Front side ribbon extenders 782 feed front side ribbons 880 upwards through front side ribbon cutters 780 to provide a small length of ribbon for grabbing by front side ribbon grabbers 740 when tabbing the next wafer. Back side ribbon extenders 783 feed back side ribbons 881 upwards through back side ribbon cutters 781 to provide a small length of ribbon for grabbing by back side ribbon grabbers 741 when tabbing the next wafer.

FIG. 15K is a schematic view of an alternative method to that shown in FIG. 15H for soldering ribbons 880 and 881 to wafer 790. All components of the tabbing mechanism are the same as in FIG. 15H, except for the front and back soldering heads 2102 and 2104, respectively, which differ from the soldering heads 102 and 104 illustrated in FIG. 15H by the addition of a capability for blowing gas (either air or an inert gas, such as Argon or Nitrogen, for example), against the front and back side ribbons 880 and 881, respectively, during the ribbon soldering operation. Front side soldering heads 2102 blow gas 2103 against front side ribbons 880, forcing them against front side contact areas on wafer 790. Gas 2103 may be heated to aid in bringing ribbons 880 to the required soldering temperature. Front side soldering heads 2102 simultaneously heat front side ribbons 880 inductively to the required soldering temperature.

Similarly, back side soldering heads 2104 blow gas 2105 against back side ribbons 881, forcing them against back side contact areas on wafer 790. Gas 2105 may be heated to aid in bringing ribbons 881 to the required soldering temperature. Back side soldering heads 2104 simultaneously heat back side ribbons 881 inductively to the required soldering temperature.

It is preferable that the front side and back side soldering heads, 2102 and 2104, respectively, blow gas towards wafer 790 approximately simultaneously to ensure that no unnecessary asymmetrical (front-to-back) forces are applied to wafer. 790. In particular, if the back side soldering heads 2104 were to blow gas 2105 towards the back side of wafer 790 before the front side soldering heads 2102 have started blowing gas 2103 towards the front side of wafer 790, it is possible that wafer 790 could be disconnected from vacuum arm 402, causing either wafer misalignment or wafer damage. After soldering is complete, ribbon grabbers 740 and 741 release ribbons 880 and 881, respectively.

FIG. 16 shows a schematic top view of a PV cell, illustrating zones for soldering the ribbon to the wafer. Each ribbon can be heated in a number of separate sections, (where seven are shown here). The left ribbon is divided up into seven sections 241-247, and the right ribbon is divided up into seven sections 251-257. These sections do not correspond to physical structures on the ribbon, but rather, to small heater elements in either the front or back soldering heads, 102 and 104, respectively. For example, if induction heating of the front and back ribbons 880 and 881, respectively, is employed, then sections 241-247 and 251-257 would correspond to individually-controlled RF coils within the (nonconducting) solder head structures. In this case, sequence #1 in Table I would correspond to exciting all RF coils simultaneously. In general, due to differential thermal expansion between the ribbons and the wafer, such a sequence would be undesirable and might lead to wafer distortion and/or failure of the solder joint between the ribbons and the wafer. Sequence #2 would correspond to the opposite case—sequential excitation of the RF induction coils from one end of the ribbons (both front and back) to the other end of the ribbons. Sequences #3-5 correspond to intermediate approaches where several RF coils are excited at the same time.

TABLE I
Various possible excitation sequences for the
heater elements in the ribbon soldering heads.

| | Left Ribbon | | | | | | |
|---|---|---|---|---|---|---|---|
| | 241 | 242 | 243 | 244 | 245 | 246 | 247 |
| | Right Ribbon | | | | | | |
| | 251 | 252 | 253 | 254 | 255 | 256 | 257 |
| Sequence #1 | 1 | 1 | 1 | 1 | 1 | 1 | 1 |
| Sequence #2 | 1 | 2 | 3 | 4 | 5 | 6 | 7 |
| Sequence #3 | 1 | 2 | 1 | 2 | 1 | 2 | 1 |
| Sequence #4 | 1 | 2 | 3 | 1 | 2 | 3 | 1 |
| Sequence #5 | 1 | 2 | 3 | 4 | 1 | 2 | 3 |

If infrared heating is employed, the sequences can be the same as for RF induction heating, but now individual heat lamps within the front and back soldering heads are energized according to the sequences in Table I. Other heating methods for soldering are familiar to those skilled in the art—the only requirement for any of these is that there must a segmentation of the heating means corresponding to the segments shown in FIG. 16 and Table I. For maximum system throughput, it is preferable that the heater elements (of whatever type) must be able to rapidly heat up and cool down. This capability also ensures that there will be minimal overall heating of the wafer, which could cause thermally-induced stress damage.

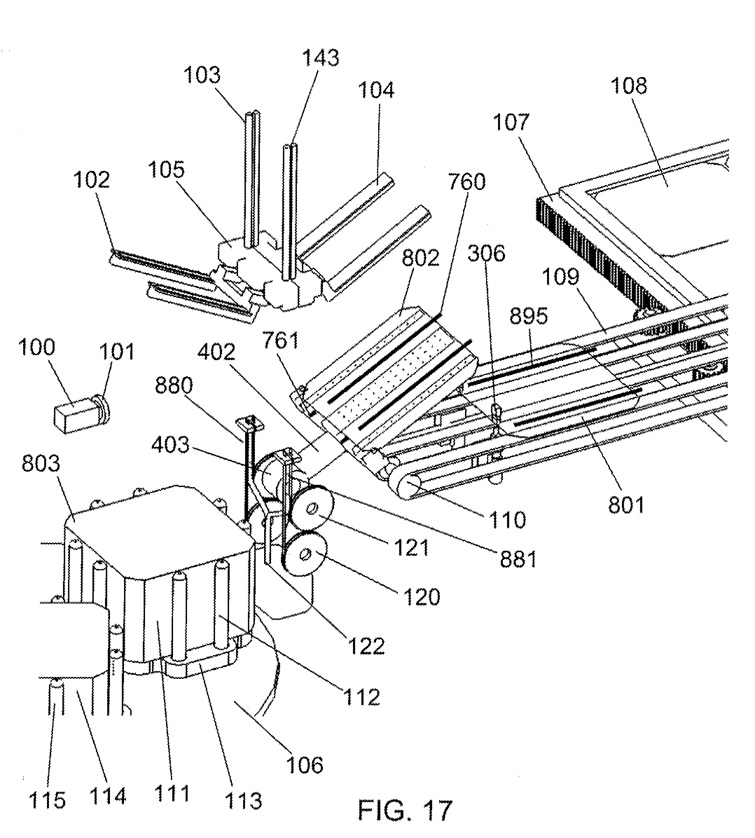

FIG. 17 shows a close-up isometric view of the tabber-stringer system performing the wafer transfer to the belt operation. Following successful completion of the soldering operation in FIG. 13 and the subsequent swinging back of the front and back soldering heads 102 and 104, respectively, vacuum arm 402 and the vacuum-attached wafer 802 swing approximately 90° to the right to place wafer 802 onto belts 109 supported by rollers 110. Wafer 801 has already been indexed one step to the right, where the distance corresponding to a single step is the wafer dimension (parallel to belts 109) plus an additional few millimeters in addition to allow room for stringing the wafers together (see FIGS. 19-21). Stringer soldering heads 306 are positioned to allow wafer 802 to swing onto belts 109 unimpeded.

FIG. 18 shows a close-up isometric view of the tabber-stringer system performing the wafer stringing operation. Wafer 802 is now supported by belts 109, with vacuum arm 402 below and between belts 109. The three-tined fork design of vacuum arm 402 enables the interleaving of vacuum arm 402 with belts 109. Stringer soldering heads 306 are used to solder front side ribbons to back side ribbons as shown in FIGS. 19-21 for three different stringing methods.

FIG. 19 is a schematic side cross-sectional view of the tab-over method of stringing. Three wafers 1001-1003 being stringed are shown (1001 and 1003 are shown only partially). Insulating strips 1020 and 1021 are attached to the edges of wafer 1001 and 1002, respectively, in line with ribbons 1010-1015 (strips 1020 and 1021 are attached prior to soldering of ribbons). Insulating strips 1022 and 1023 on the front sides of wafers 1002 and 1003, respectively, are also in line with ribbons 1010-1015 (strips 1022 and 1023 are attached prior to soldering of ribbons). Ribbons 1010 and 1013 are soldered to wafer 1001 during the tabbing operation in FIG. 13. Similarly, ribbons 1011 and 1014 are soldered to wafer 1002, and ribbons 1012 and 1015 are soldered to wafer 1003 also during the tabbing operation. The stringing operation in FIG. 18 for this method of stringing corresponds to bringing stringer soldering heads 1030 (corresponding to stringer soldering heads 306 in FIG. 18) down on front side ribbons 1010 (soldered to the front side of wafer 1001), which are on top of front side ribbons 1014 (soldered to the back side of wafer 1002). Stringer soldering heads 1030 heat both ribbons 1010 and 1014 to solder them together, while insulating strip 1022 protects wafer 1002 from excessive heating. In FIG. 19, wafers 1002 and 1003 were stringed together in an earlier operation identical to that shown here.

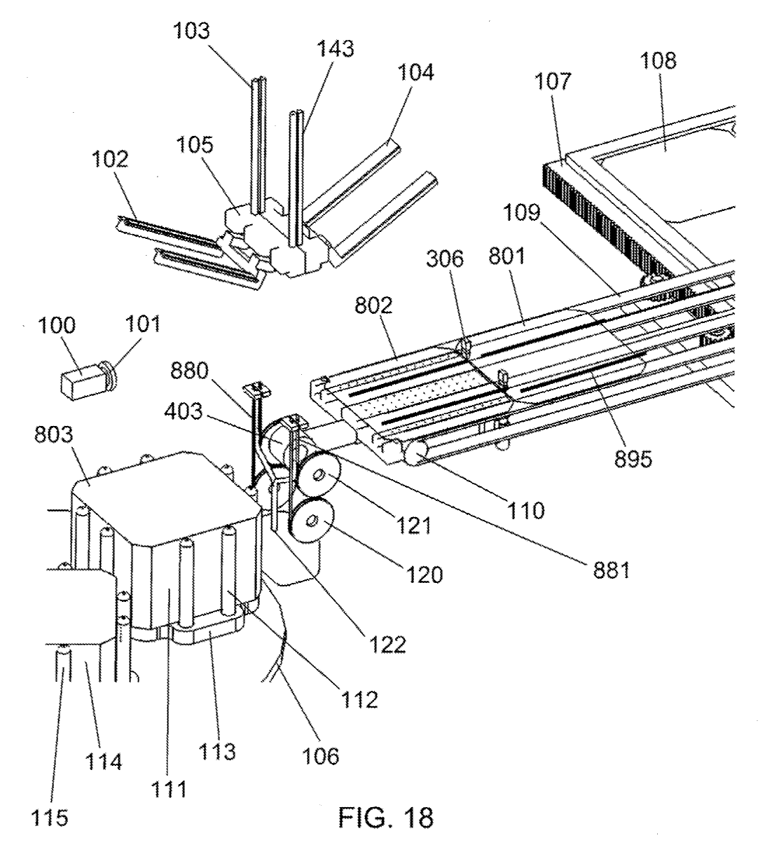

FIG. 20 is a schematic side cross-sectional view of the extended tab method of stringing. Three wafers 1101-1103 being stringed are shown (1101 and 1103 are shown only partially). Three front side ribbons 1110-1112 and three back side ribbons 1113-1115 are shown. Front side ribbon 1110 and back side ribbon 1114 are being soldered together by stringer soldering heads 1120 and 1121 (corresponding to stringer soldering heads 306 in FIG. 18). Front side ribbon 1111 and back side ribbon 1115 were soldered together in an earlier operation identical to that shown here. Note that FIG. 20 illustrates the reason for the offset of the front side ribbons relative to the back side ribbons (see FIG. 15G).

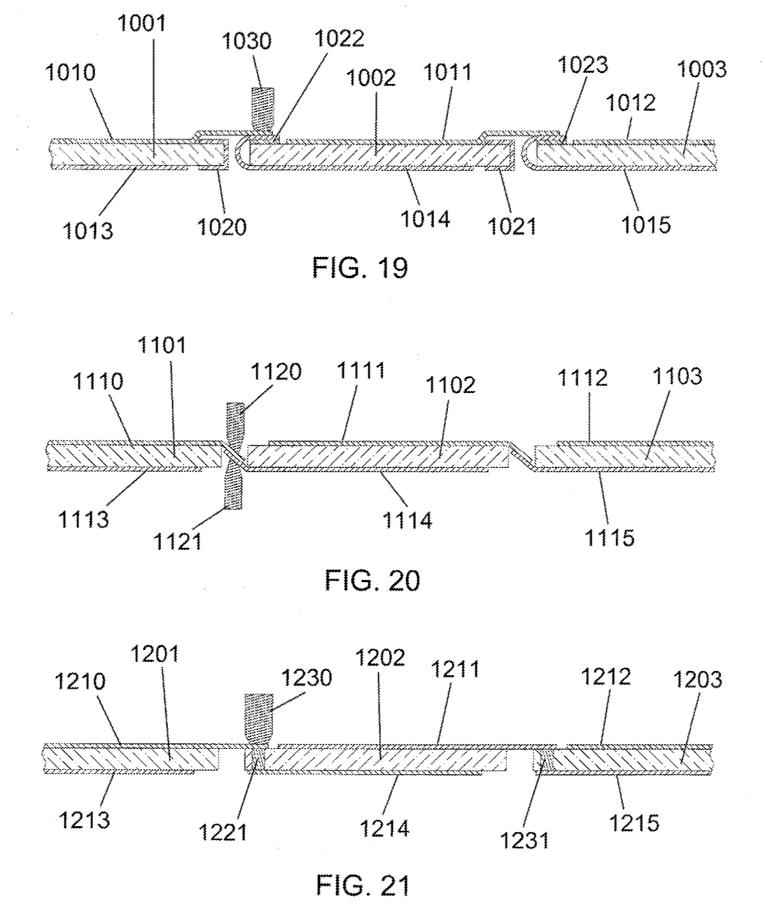

FIG. 21 is a schematic side cross-sectional view of the conductive path method of stringing. Three wafers 1201-1203 being stringed are shown (1201 and 1203 are shown only partially). In this method, the PV cells are fabricated with conductive paths (vias) 1221 and 1231 through from the front side to the back side of wafers 1202 and 1203, respectively (the conductive path is not shown for wafer 1201). This method eliminates the need for the front side ribbon to bend down between wafers (e.g., wafers 1101 and 1102 in FIG. 20). Since the front side ribbons remain in the plane of the wafer front sides, closer packing of PV cells within the solar array being manufactured is possible. Stringer soldering heads 1230 (corresponding to stringer soldering heads 306 in FIG. 18) are shown soldering front side ribbon 1210 on wafer 1201 to conductive path 1221 on wafer 1202. Conductive path 1221 was previously soldered to back side ribbon 1214 during the tabbing operation. Front side ribbon 1211 on wafer 1202 and conductive path 1231 on wafer 1203 were have already been soldered together in an earlier operation identical to that shown here.

An alternative method for electrically connecting (stringing) successive wafers together is spot welding, instead of soldering. In this case, the solder stringing heads 306 in FIG. 18 would be configured as spot welding heads. As is familiar to those skilled in the art, spot welding involves a momentary passage of a high electrical current from one welding head to an opposing welding head, through two pieces of metal which are to be spot welded together. In FIG. 19, upper spot welding head 306 could supply a momentary high current, which would then flow out of the head 306, through the two ribbons to be electrically connected together, and then into an opposing lower spot welding head. The benefit of spot welding over soldering is the substantially reduced amount of overall heating of the wafers being stringed, since the heat pulse required to spot weld the ribbons together will not spread to the wafers onto which the ribbons were soldered during the tabbing operation. Reference to FIG. 19 shows that the soldering heads 1030 would now be configured as spot welding heads. The other electrode required for the spot welding operation in FIG. 19 would have to make electrical contact to ribbon 1014 to complete the welding circuit. Reference to FIG. 20 shows that soldering heads 1120 and 1121 would be configured as upper and lower spot welding heads in this alternative embodiment. Finally, reference to FIG. 21 shows that soldering heads 1230 would be configured as spot welding heads. The other electrode required for the spot welding operation in FIG. 21 would have to make electrical contact to ribbon 1214 to complete the welding circuit.

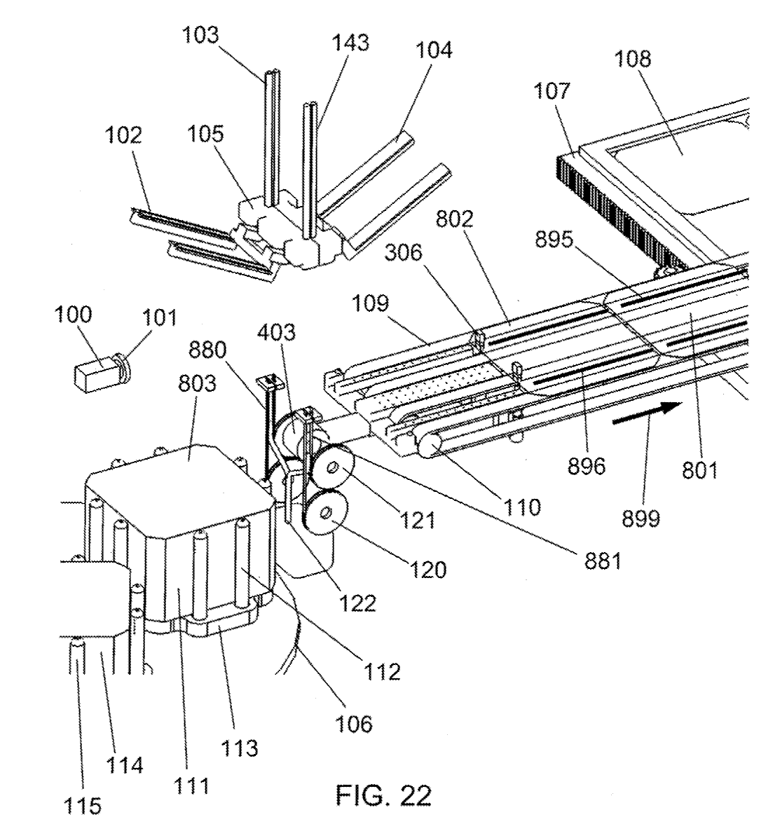

FIG. 22 shows a close-up isometric view of the tabber-stringer system performing the wafer indexing operation. As shown in FIG. 18, vacuum arm 402 has swung to the right 90° to position wafer 802 on belts 109 supported by rollers 110. The vacuum clamping between wafer 802 and vacuum arm 402 is then turned off, freeing wafer 802 from being clamped to vacuum arm 402. Now wafer 802 is entirely supported by belts 109. Arrow 899 illustrates the motion of belts 109 carrying wafers 801 and 802 (which are stringed together) a distance corresponding to the dimension of wafer 802 parallel to belts 109 plus a small additional increment (typically a few mm) to allow room for soldering front and back side ribbons together between the neighboring wafers. As the string being assembled grows longer, the front end (wafers first stringed together) will extend out onto belt 302 supported by rollers 301 (see FIG. 2).

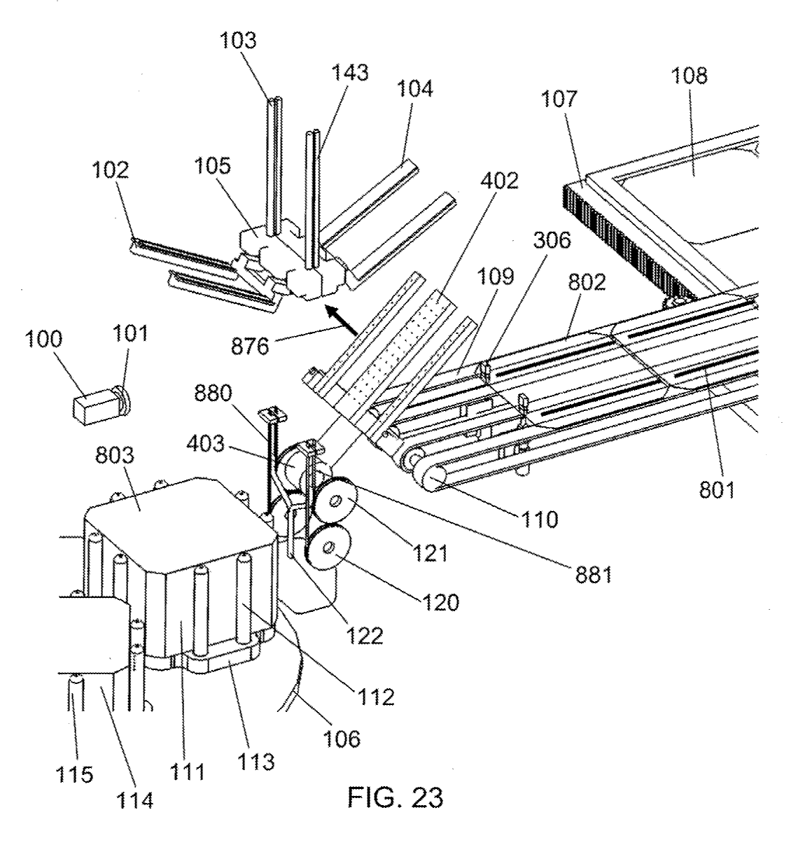

FIG. 23 shows a close-up isometric view of the tabber-stringer system resetting the vacuum arm. Once the indexing operation in FIG. 22 has been completed, vacuum arm 402 is free to swing back to the left of the figure (arrow 876). The interleaving of the tines of the fork-like vacuum arm 402 between belts 109 can be seen.

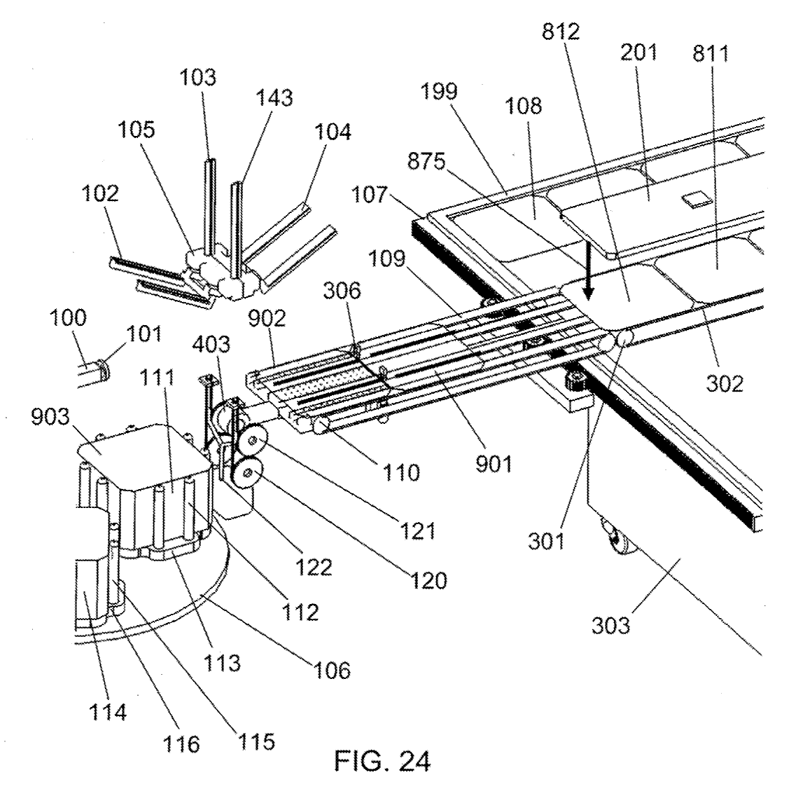

FIG. 24 shows a close-up isometric view of the tabber-stringer system performing the stringing and buffering operation. Wafers 811 and 812 are the last two wafers of the previously-completed string which is now entirely supported by belt 302 running on rollers 301. Vacuum chuck 201 is moving down (arrow 875) to lift the completed string off belt 302 for loading into the solar array frame 199 supported by table 107 on support legs 303. Wafers 901 and 902 have already been stringed together as the beginning of the next string. Note that the dual-belt configuration (belts 109 and belt 302) enables improved overall system throughput since the loading of completed strings can take place simultaneously with the initial soldering of the next string.

The invention above has been described for the case of two interconnections ribbons per PV cell, but can be extended to the case of PV cells with any number of interconnection ribbons per PV cell, as would be familiar to one skilled in the art.

Front side and back side soldering heads have been shown as separate elements for each of the front side and back side ribbons, respectively. The front side soldering heads could be combined into one or more elements, each soldering more than one ribbon to the front side of the wafer being tabbed. Similarly, the back side soldering heads could be combined into one or more elements, each soldering more than one ribbon to the back side of the ribbon being tabbed.

Although a vacuum arm has been shown for transferring wafers between the bins, tabbing subsystem and stringing subsystem, other means of wafer transport such as electrostatic clamping arms may be used within the scope of the present invention. The vacuum arm has been illustrated as a simple swinging arm, however, more complex types of robotic wafer transport mechanisms could perform the required functions of wafer transfer between the bins, tabbing subsystem and stringing subsystem, as is familiar to those skilled in the art.

Wafers are shown being supported on multiple belts in the stringing subsystem, however other support and transfer means may be employed within the scope of the present invention, such as a single moving belt, a multiplicity of support rollers, etc.

Within the solar cell array subsystem, completed strings are shown being supported by a secondary belt mechanism, however other support and transfer means may be employed within the scope of the present invention, such as a multiple moving belts, a multiplicity of support rollers, etc.

Within the solar cell array subsystem, a single vacuum chuck is shown for lifting and placing completed strings into the solar array being manufactured. Alternative lifting and placing mechanisms are possible within the scope of the present invention, such as electrostatic clamping chucks, etc.

What is claimed is:

1. A system, comprising means for affixing a multiplicity of top interconnect tabs (ribbons) and a multiplicity of bottom interconnect tabs to a first photovoltaic cell, the top interconnect tabs overlapping a first edge of the first photovoltaic cell and the bottom interconnect tabs overlapping a second edge of the first photovoltaic cell; and means for assembling the first photovoltaic cell to a second photovoltaic cell by way of the first and second interconnect tabs, the means for affixing being separate from the means for assembling; and the system including means for handling a photovoltaic cell configured to position the first photovoltaic cell in a first position for the affixing of the multiplicities of top and bottom interconnect tabs and in a second position for passing to the means for assembling.

2. A method, comprising affixing a multiplicity of top interconnect tabs (ribbons) and a multiplicity of bottom interconnect tabs to a first photovoltaic cell, the top interconnect tabs overlapping a first edge of the first photovoltaic cell and the bottom interconnect tabs overlapping a second edge of the first photovoltaic cell; and assembling the first photovoltaic cell to a second photovoltaic cell by way of the first and second interconnect tabs, wherein the first photovoltaic cell is oriented in a first position for the affixing of the top and bottom interconnect tabs and in a second position for assembly to the second photovoltaic cell.

3. A method for aligning a photovoltaic cell for processing operations, comprising:
configuring a system for electrically connecting together a multiplicity of photovoltaic cells, said system comprising a transfer arm assembly, comprising a transfer arm that includes means for applying a clamping force between individual ones of said photovoltaic cells and said transfer arm; and an actuator for moving said transfer arm in a vertical plane through an angle greater than or equal to 90 degrees;
clamping an individual one of said photovoltaic cells to said transfer arm;
moving said transfer arm to a first orientation in which said individual one of said photovoltaic cells is above, and supported by, said transfer arm;
releasing said individual one of said photovoltaic cells;
allowing said individual one of said photovoltaic cells to slide along an upper surface of said transfer arm to become positioned against means for locating said individual one of said photovoltaic cells in a second orientation for subsequent processing; and
again clamping said individual one of said photovoltaic cells to said transfer arm.

4. A system for electrically connecting together a multiplicity of photovoltaic cells, comprising:
a first bin containing a multiplicity of photovoltaic cells in a vertical stack;
a wafer transfer system to remove respective, individual photovoltaic cells from said vertical stack of photovoltaic cells contained in said first bin, said wafer transfer system comprising:
a transfer arm assembly, comprising a transfer arm that includes means for applying a clamping force between ones of said respective, individual photovoltaic cells and said transfer arm;
an actuator for moving said transfer arm in a vertical plane through an angle greater than or equal to 90 degrees;
means for optically inspecting said respective, individual photovoltaic cells when supported in an approximately vertical orientation; and
an image processing system electrically connected to said means for optically inspecting and configured to analyze said respective, individual photovoltaic cells for defects.

5. The system of claim 4, wherein said means for applying a clamping force between said photovoltaic cell and said transfer arm is a vacuum chuck.

6. The system of claim 4, wherein said means for applying a clamping force comprises an electrostatic chuck.

7. The system of claim 4, further comprising:
a turntable supporting said first bin; and
a second bin, supported by said turntable,
wherein said turntable is rotatable to position said second bin for loading of defective ones of said respective, individual photovoltaic cells by said transfer arm assembly.

8. The system of claim 4, further comprising a tabbing subsystem, said tabbing subsystem comprising:
means for locating a plurality of ribbons in alignment with a plurality of corresponding contact areas on said respective, individual photovoltaic cells;
means for soldering each of said plurality of ribbons to corresponding ones of said contact areas on said respective, individual photovoltaic cells.

9. The system of claim 8, wherein said means for soldering comprises a plurality of soldering heads.

10. The system of claim 8, further comprising means for applying flux to said ribbons prior to soldering of said ribbons to said corresponding ones of said contact areas.

11. The system of claim 9, wherein each of said soldering heads is configured to press one of said plurality of ribbons against one of said corresponding contact areas, and wherein said soldering heads simultaneously heat said ribbons to a required soldering temperature.

12. The system of claim 9, wherein each of said soldering heads is configured to blow gas against a corresponding one of said plurality of ribbons in order to press said corresponding one of said plurality of ribbons against a corresponding one of said contact areas, and wherein said soldering heads simultaneously inductively heat said ribbons to a required soldering temperature.

13. The system of claim 9, wherein each of said soldering heads is configured with a multiplicity of individually controlled heater elements.

14. The system of claim 13, wherein each of said individually controlled heater elements is excitable in a timed sequence.

15. A method for electrically connecting together a pair of photovoltaic cells, said pair comprising a first cell and a second cell, said method comprising the steps of:
configuring said first cell with a first plurality of ribbons on a front side of said first cell, wherein said first plurality of ribbons makes electrical contact with contact areas on said front side of said first cell;
configuring said second cell with a second plurality of ribbons on a back side of said second cell, wherein said second plurality of ribbons makes electrical contact with contact areas on said back side of said second cell, and wherein an end of each of said second plurality of ribbons wraps around an edge of said second cell and is affixed to a front surface of said second cell, near said edge of said second cell;
supporting said first and second cells in an approximately coplanar configuration, with a separation between neighboring sides of said first and second cells;
positioning an end of each ribbon from said first plurality of ribbons above an end of each ribbon from said second plurality of ribbons at said location where said ribbon from said second plurality of ribbons is affixed to said front surface of said second cell; and
joining corresponding ends of said ribbons from said first and second pluralities of ribbons together.

16. The method of claim 15, wherein said joining comprises spot welding together said corresponding ends of said ribbons from said first and second pluralities of ribbons.

17. The method of claim 15, wherein said joining comprises soldering together said corresponding ends of said ribbons from said first and second pluralities of ribbons.

18. A method for electrically connecting together a pair of photovoltaic cells, said pair comprising a first cell and a second cell, said method comprising the steps of:
configuring said first cell with a first plurality of ribbons on a front side of said first cell, wherein said first plurality of ribbons makes electrical contact with contact areas on said front side of said first cell;
configuring said second cell with a second plurality of ribbons on a back side of said second cell, wherein said second plurality of ribbons makes electrical contact with contact areas on said back side of said second cell;
supporting said pair of photovoltaic cells in an approximately coplanar configuration, with a gap between neighboring sides of said pair of photovoltaic cells;
orienting each of said pair of photovoltaic cells to position an end of a corresponding one of said first plurality of ribbons approximately above an end of a corresponding one of said second plurality of ribbons within said gap between said neighboring sides of said pair of photovoltaic cells;
configuring a pair of joining heads to move along an axis of motion, wherein said axis of motion is approximately perpendicular to said pair of photovoltaic cells, and said axis of motion passes through said gap between said neighboring sides of said pair of photovoltaic cells, such that said pair of joining heads clamps said end of said corresponding one of said first plurality of ribbons against said end of said corresponding one of said second plurality of ribbons; and
joining said corresponding one of said first plurality of ribbons to said end of said corresponding one of said second plurality of ribbons using said joining heads.

19. The method of claim 18, wherein said joining heads comprise spot welding heads, and said joining comprises spot welding of said end of said corresponding one of said first plurality of ribbons to said end of said corresponding one of said second plurality of ribbons.

20. The method of claim 18, wherein said joining heads comprise soldering heads, and said joining comprises heating said soldering heads to solder said end of said corresponding one of said first plurality of ribbons to said end of said corresponding one of said second plurality of ribbons

21. A method for electrically connecting together a pair of photovoltaic cells, said pair comprising a first cell and a second cell, comprising the steps of:
configuring said first cell with a first plurality of ribbons on a front side of said first cell, wherein said first plurality of ribbons makes electrical contact with contact areas on said front side of said first cell;
configuring said second cell with a second plurality of ribbons on a back side of said second cell, wherein:
said second plurality of ribbons makes electrical contact with contact areas on said back side of said second cell;
said second cell further comprises an array of vias extending from a front surface to a back surface of said second cell; and
said array of vias is in electrical contact with said second plurality of ribbons on said back side of said second cell;
supporting said pair of photovoltaic cells in an approximately coplanar configuration, with a gap between neighboring sides of said pair of photovoltaic cells;
positioning a corresponding end of each ribbon from said first plurality of ribbons above a corresponding one of said array of vias on said second photovoltaic cell; and
joining each said corresponding end of said ribbons from said first plurality of ribbons to said corresponding one of said array of vias on said second photovoltaic cell.

22. The method of claim 21, wherein said joining comprises spot welding each said corresponding end of said ribbons from said first plurality of ribbons to said corresponding one of said array of vias on said second photovoltaic cell.

23. The method of claim 21, wherein said joining comprises soldering each said corresponding end of said ribbons from said first plurality of ribbons to said corresponding one of said array of vias on said second photovoltaic cell.

24. A method of stringing a pair of photovoltaic cells together, said pair comprising a first cell and a second cell, said method comprising the steps of:
configuring said first cell with a first plurality of ribbons on a front side of said first cell, wherein said first plurality of ribbons makes electrical contact with contact areas on said front side of said first cell;
configuring said second cell with a second plurality of ribbons on a back side of said second cell, wherein said second plurality of ribbons makes electrical contact with contact areas on said back side of said second cell;
orienting each of said pair of photovoltaic cells to position a corresponding one of said first plurality of ribbons approximately above a corresponding one of said second plurality of ribbons; and
electrically connecting together each said corresponding one of said first plurality of ribbons to said corresponding one of said second plurality of ribbons.

25. A method for aligning a photovoltaic cell for processing operations, comprising:
configuring a system for electrically connecting together a multiplicity of photovoltaic cells, said comprising a transfer arm assembly having a transfer arm with means for applying a clamping force between said photovoltaic cell and said transfer arm; a first actuator for moving said transfer arm through an angle in a vertical plane greater than or equal to 90 degrees; a second actuator for moving said transfer arm along an axis perpendicular to said vertical plane; a third actuator for moving said transfer arm radially within said vertical plane; means for optically inspecting said photovoltaic cell when supported in an inspection orientation; and an image processing system electrically connected to said means for optically inspecting, wherein said image processing system is configured to analyze said photovoltaic cell for defects;
clamping said photovoltaic cell to said transfer arm;
moving said transfer arm to the inspection orientation;
inspecting said photovoltaic cell and determining relative locations of a plurality of alignment marks on said photovoltaic cell relative to said transfer arm; and
moving said photovoltaic cell on said transfer arm by means of said second and third actuators to a predetermined position relative to said transfer arm.
